(19) United States
(12) Patent Application Publication
(10) Pub. No.: US 2021/0233798 A1
(43) Pub. Date: Jul. 29, 2021

(54) DEGAS CHAMBER LIFT HOOP

(71) Applicant: Fabworx Solutions, Inc., Austin, TX (US)

(72) Inventors: Daniel Alaniz, Austin, TX (US); Thomas Walton, Manor, TX (US); Michael Dailey, Austin, TX (US)

(21) Appl. No.: 17/059,437

(22) PCT Filed: May 29, 2019
(86) PCT No.: PCT/US2019/034477

§ 371 Date: Nov. 29, 2020

Related U.S. Application Data
(60) Provisional application No. 62/677,192, filed on May 29, 2018.

(51) Int. Cl. H01L 21/687

(52) U.S. Cl. CPC H01L 21/68742; H01L 21/68785; H01L 21/68707; H01L 21/6875; H01L 21/68735

(57) ABSTRACT

A lift hoop is provided which includes a frame having a central opening, and a plurality of wafer support structures disposed on the frame. Each of the plurality of wafer support structures includes a base which is attached to the frame, and fingers which are mounted with threaded fasteners to the base and which extends from the base in the direction of the central opening. Each of the plurality of fingers is equipped with a protrusion (bump) upon which a wafer sits, and a stop. The stop is spaced apart from the protrusion. The stop has a non-planar surface which faces the central opening, and contains a point that forms the shortest distance between the stop and the protrusion.

### CROSS-REFERENCE TO RELATED APPLICATIONS

The present application is a national stage filing of PCT/US2019/034477, filed on May 29, 2019, which has the same title and the same inventors, and which is incorporated herein by reference in its entirety; which claims priority to U.S. Provisional Application No. 62/677,192, filed on May 29, 2018, which has the same title and the same inventors, and which is incorporated herein by reference in its entirety.

### FIELD OF THE DISCLOSURE

The present application relates generally to robotic lift assemblies, and more particularly to lift hoop assemblies equipped with fingers to lift and transfer wafers.

### BACKGROUND OF THE DISCLOSURE

Degassing chambers are well known in the art and are common tools in semiconductor fabrication facilities. Degassing chambers are used to implement vacuum degassing, a process in which a vacuum (typically in conjunction with a thermal cycle) is utilized to remove gases that have become entrapped in a semiconductor wafer during fabrication.

One example of a prior art degassing chamber is disclosed in U.S. Pat. No. 6,182,376 (Shin et al.), which is depicted in FIGS. 1-3 herein. The degassing chamber 11 depicted therein comprises a vacuum chamber 13 containing a heated substrate support 15. A gas inlet 17 is provided which fluidically couples the vacuum chamber 13 to a dry gas source 19. A gas outlet 21 is provided which fluidically couples the vacuum chamber 13 to a gas pump 23.

A wafer 25 is shown mounted on the heated substrate support 15. A plurality of pins 27 are positioned beneath the wafer 25 to facilitate gas flow along the backside of the wafer 25 and to reduce contact between the wafer 25 and the substrate support 15, thereby reducing the generation of particles which would be initiated by such contact. The positioning of the plurality of pins 27 is best appreciated with reference to FIG. 2.

In order to easily place and extract a wafer from the heated substrate support 15, a conventional wafer lift hoop 29 is employed. The operation of such a lift hoop is well known in the art. The wafer lift hoop 29 is equipped with three fingers 29a-c that extend underneath the wafer. This configuration, which is intended to minimize particle generation, limits wafer contact to the area above the three fingers 29a-c. More specifically, the fingers 29a-c extend upwardly from the wafer lift hoop 29 and have a wafer shelf portion 30 preferably extending inwardly a horizontal distance of between 0.030-0.050 inches.

In addition to extending beneath the wafer 25, the fingers 29a-c also comprise side portions 31a-c, respectively (see FIG. 2), which extend along the edge of the wafer 25. The configuration of the side portions is intended to reduce the generation of particles as might occur from contact therewith. In particular, the side portions are sloped to avoid contact with the edge of the wafer 25 as the wafer 25 is placed on or removed from the wafer handler (not shown). Similarly, in order to reduce contact between the wafer shelf portion 30 and the backside of the wafer 25, the fingers 29a-c have a sloped lower portion 33 which slopes away from the wafer shelf portion 30 at an angle greater than or equal to 10°. Thus, if the wafer 25 should slide off of the wafer shelf portion 30, the wafer 25 will be supported by the sloped lower portion 33, thus preventing the wafer from falling off of the device. Thus, even after the wafer lift hoop 29 has lowered (and the horizontal portion of the fingers 29a-c are housed in appropriately located recesses in the surface of the substrate support 15), the side portions 30a-c of the fingers 29a-c capture the wafer. This arrangement is intended to prevent the wafer from moving out of center, or becoming unseated from the substrate support 15.

### BRIEF DESCRIPTION OF THE DRAWINGS

FIG. 1 is a side elevational view of a prior art degassing apparatus.

FIG. 2 is a partial side elevational view providing a closer view of the wafer lift hoop of the degassing apparatus of FIG. 1.

FIG. 3 is a top elevational view of the substrate support of the degassing apparatus of FIG. 1.

FIG. 4 is a perspective view of a particular, non-limiting embodiment of a degas chamber lift hoop in accordance with the teachings herein.

FIG. 5 is an illustration of the wafer capture zones of a degas chamber lift hoop in accordance with the teachings herein as compared to a prior art degas chamber lift hoop.

FIG. 6A is a perspective view of a wafer capture arm in accordance with the teachings herein, shown with a wafer mounted thereon.

FIG. 6B is a perspective view of a prior art wafer capture arm, shown with a wafer mounted thereon.

FIG. 7 is an illustration of thermally induced warping in a prior art degas lift hoop.

FIG. 8 is a chart comparing the thermally induced vertical deflection in various components of a prior art degas chamber lift hoop and a degas chamber lift hoop in accordance with the present application.

FIG. 9A is a perspective view of a lift hoop finger wall design in accordance with the teachings herein.

FIG. 9B is a perspective view of a prior art lift hoop finger wall design.

FIG. 10 is a perspective view of a fixture for aligning a heater, end effector and lift hoop with respect to each other.

FIG. 11 is a perspective view illustrating the use of the fixture of FIG. 10 in aligning a heater, end effector and lift hoop with respect to each other.

FIGS. 12-16 are perspective views of a first particular, non-limiting embodiment of a wafer support structure for a degas chamber lift hoop in accordance with the teachings herein.

FIGS. 17-21 are perspective views of a second particular, non-limiting embodiment of a wafer support structure for a degas chamber lift hoop in accordance with the teachings herein.

FIG. 22 is a top view of the degas chamber lift hoop of FIG. 4 with the wafer support structures removed.

FIG. 23 is a bottom view of the degas chamber lift hoop of FIG. 22.

FIGS. 24-25 are perspective views of the degas chamber lift hoop of FIG. 22.

### SUMMARY OF THE DISCLOSURE

In one aspect, a lift hoop is provided which comprises (a) a frame having a central opening; (b) a plurality of wafer support structures disposed on said frame, wherein each of said plurality of wafer support structures includes a base which is attached to said frame, and a finger which is attached to said base and which extends from said base in the direction of said central opening; (c) a protrusion disposed on each of said fingers; and (d) a stop disposed upon each of said fingers and spaced apart from said protrusion, said stop having a non-planar surface which faces the central opening and which contains a point that forms the shortest distance between said stop and said protrusion.

In another aspect, a method for making a lift hoop is provided. The method comprises (a) providing a frame having a central opening therein; (b) thermally annealing the frame while applying pressure to the frame; and (c) releasably attaching a plurality of wafer support structures to said frame, wherein each of said plurality of wafer support structures includes (a) a base which is removably attached to said frame, (b) a finger which is attached to said base and which extends from said base in the direction of said central opening, (c) a protrusion disposed on said finger, and (d) a stop disposed upon said finger and spaced apart from said protrusion.

In a further aspect, a method is provided for aligning an end effector blade with a degas chamber. The method comprises (a) providing an end effector blade with a keying aperture disposed therein; (b) providing a degas chamber having a lift hoop and heater pedestal, wherein said heater pedestal has a flattened surface with a centrally located aperture therein, and wherein said lift hoop includes a frame with a central opening therein, and a plurality of wafer support structures disposed on said frame, wherein each of said plurality of wafer support structures includes a base which is attached to said frame, and a finger which is attached to said base and which extends from said base in the direction of said central opening, and wherein each of said plurality of wafer support structures further includes a protrusion disposed on said finger; (c) providing a fixture having a central hub with a plurality of arms extending therefrom, wherein said hub has a central aperture therein, and wherein each of said plurality of arms has a peripheral aperture in a terminal portion thereof; (d) placing said fixture on said lift hoop such that each of said peripheral apertures engages a protrusion of one of said fingers, and such that the central aperture in said fixture is coaxially aligned with the centrally located aperture in said heater pedestal; and (e) manipulating the position of the end effector until a pin inserted through the central aperture in said hub passes through the keying aperture in said end effector blade and into the centrally located aperture in said heater pedestal.

### DETAILED DESCRIPTION

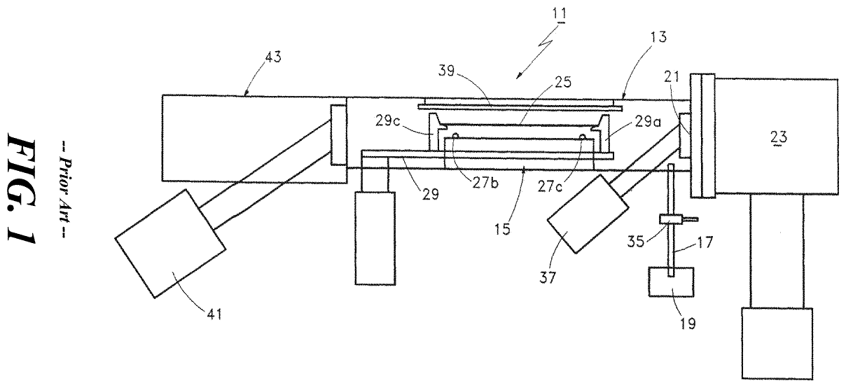

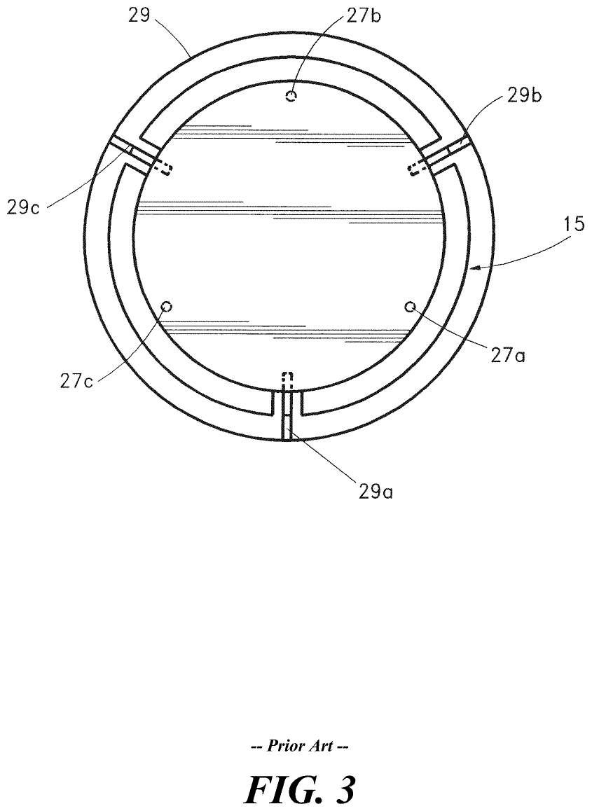

While the device depicted in FIGS. 1-3 may have some desirable attributes, it also suffers from a number of infirmities. Many of these infirmities are attributable to the lift hoop utilized therein.

For example, the wafer capture zone created by the three lift fingers of the lift hoop is very tight. In many 300 mm wafer implementations, the wafer capture zone is only about 0.63 mm larger than the wafer itself. This already limited wafer capture zone has been found to undergo further reductions as a result of heat-induced warping in the lift hoop.

Moreover, while the design of the device depicted in FIGS. 1-3 was intended to minimize particle generation, in practice, it has been found that the device contains multiple features that may still contribute significantly to particle generation. For example, the interior facing walls of the fingers on the device are equipped with flat surfaces that experience significant contact with the edge of a wafer. Similarly, the fingers are equipped with bumps that the wafer rests upon. However, both of these surfaces typically have a relatively rough finish, which exacerbates particle generation.

Finally, the standard operating procedure (SOP) for alignment of the lift hoop relies on the eyesight of the human technician. This is found to result in frequent wafer misplacement and frequent contact between the wafer and the finger walls of the lift hoop, which again results in more particle generation.

It has now been found that some or all of the foregoing infirmities may be overcome with the devices and methodologies disclosed herein. These devices and methodologies may be appreciated with respect to the embodiments depicted in the drawings herein.

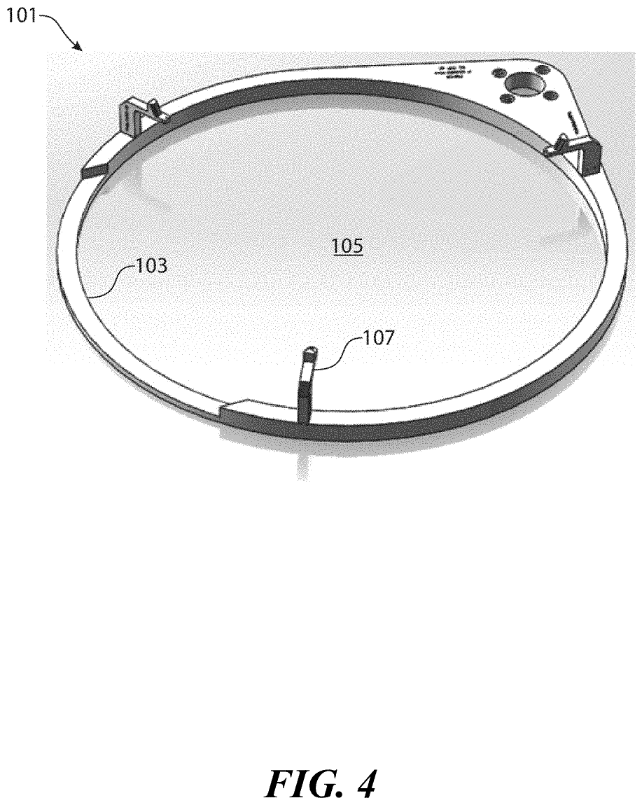

FIG. 4 depicts a particular, non-limiting embodiment of a lift hoop in accordance with the teachings herein. As seen therein, the lift hoop 101 depicted comprises a frame 103 having a (preferably circular) central opening 105 therein. A plurality of wafer support structures 107 are disposed on the frame about the periphery of the central opening.

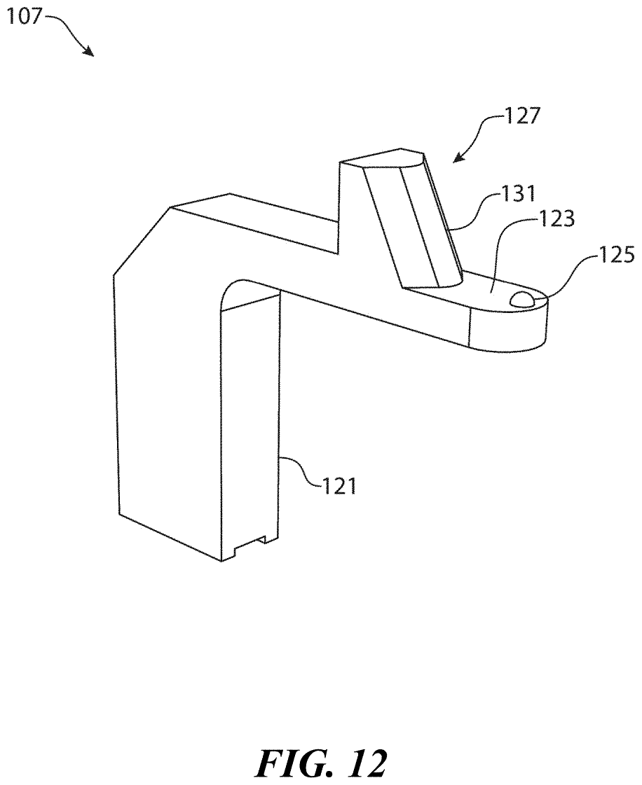

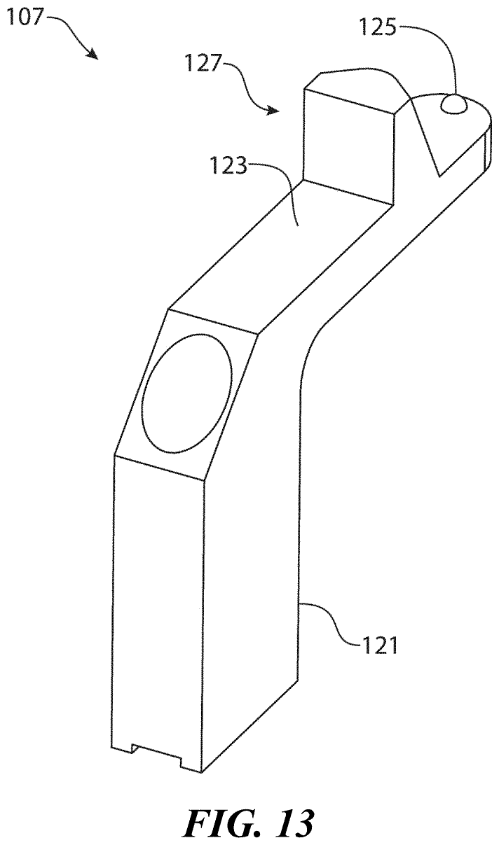

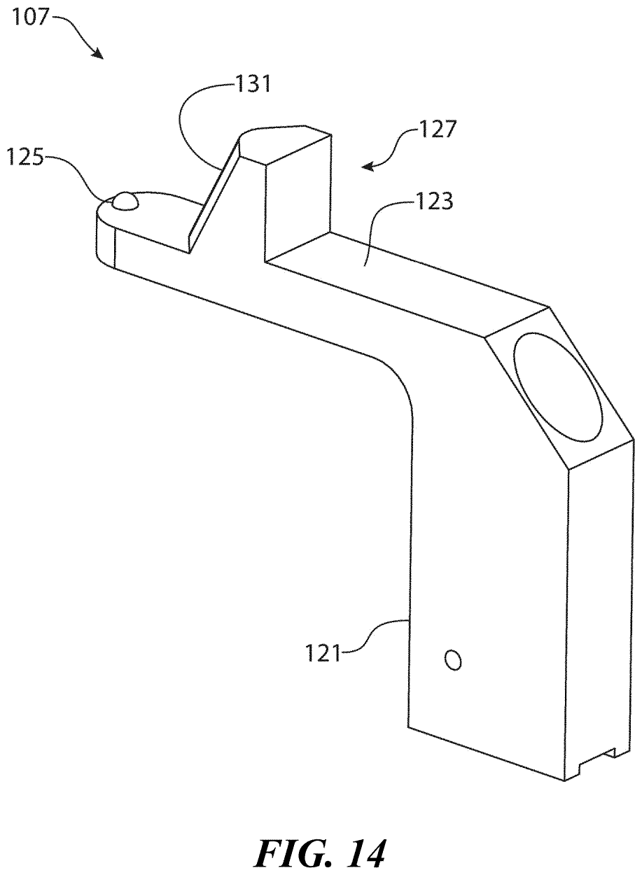

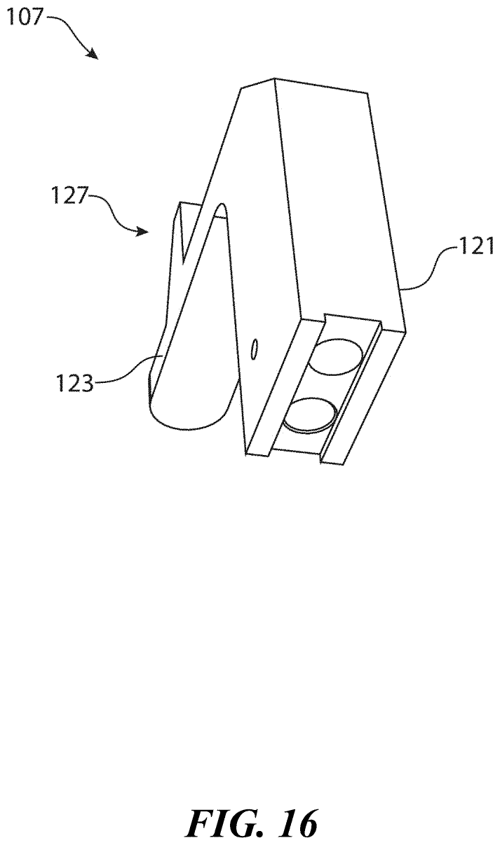

The wafer support structures 107 are illustrated in greater detail in FIGS. 12-16. As seen therein, each wafer support structure 107 has a base 121 with a finger 123 protruding therefrom and toward the central opening 105 (see FIG. 4). The base 121 is preferably releasably attached to the frame 103 (see FIG. 4) by way of one or more screws or other suitable fasteners. Each finger 123 is equipped with a (preferably hemispherical) protrusion 125 on the distal end thereof which supports a wafer. Each finger 123 is further equipped with a stop 127 which is spaced apart from the protrusion 125.

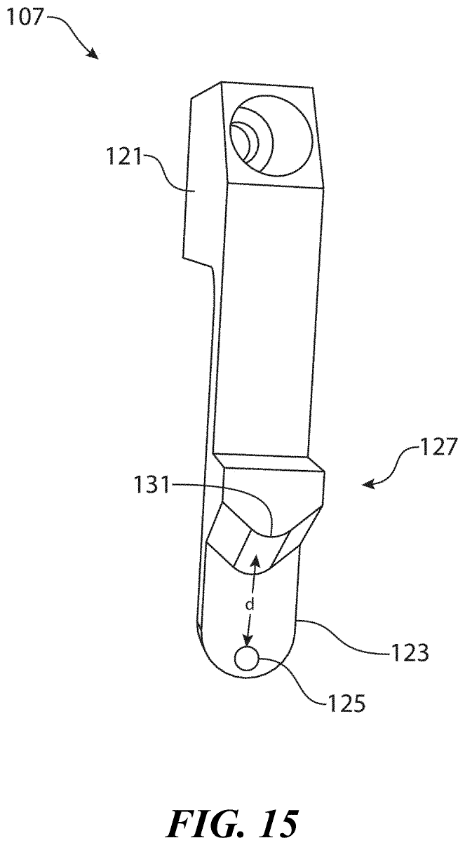

The stop 127 of the wafer support structure 107 has a (preferably non-planar) contact surface 131. In the particular embodiment depicted, this contact surface 131 is beveled or faceted, though in other embodiments in may be rounded. Preferably, however, the contact surface 131 contains a point or locus which forms the shortest distance d between said stop and said protrusion (see FIG. 15), and which serves as a wafer contact surface (note that this point or locus will typically lie in a plane which is tangential to the protrusion 125 and which intersects the contact surface 131 of the stop 127). Without wishing to be bound by theory, the use of a contact surface 131 of this type is believed to reduce particle generation by providing a smaller area of contact in the event that the wafer comes into contact with the stop 127.

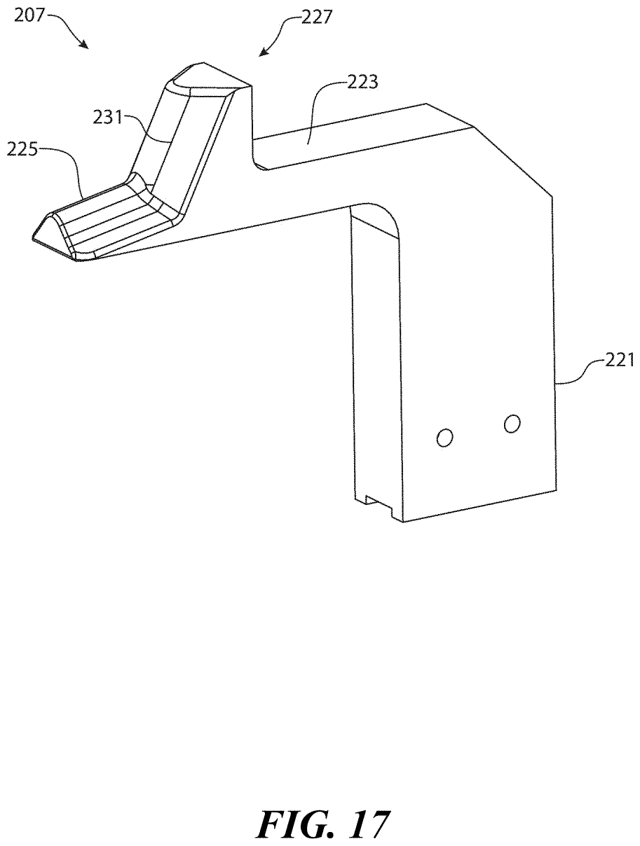

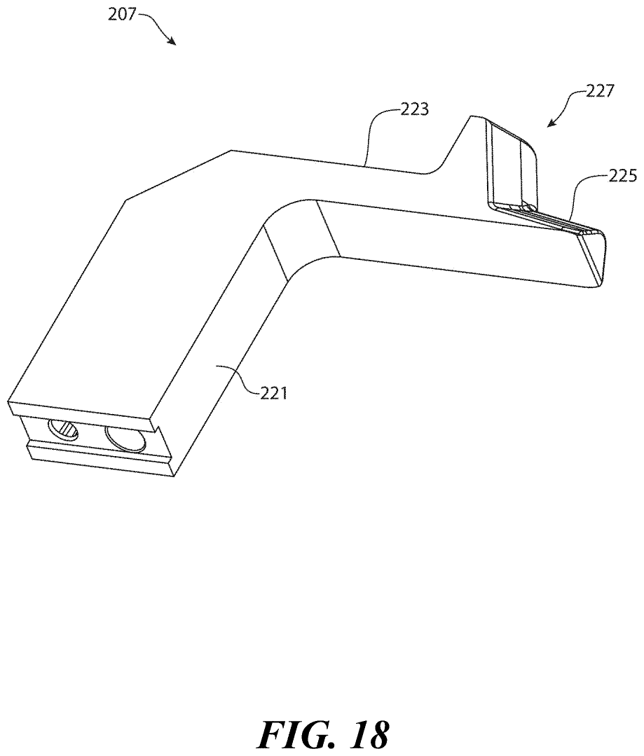

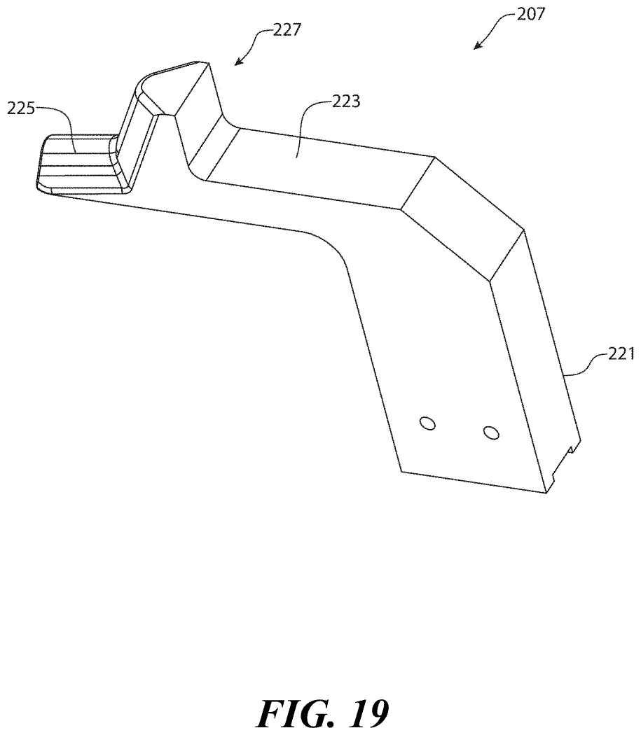

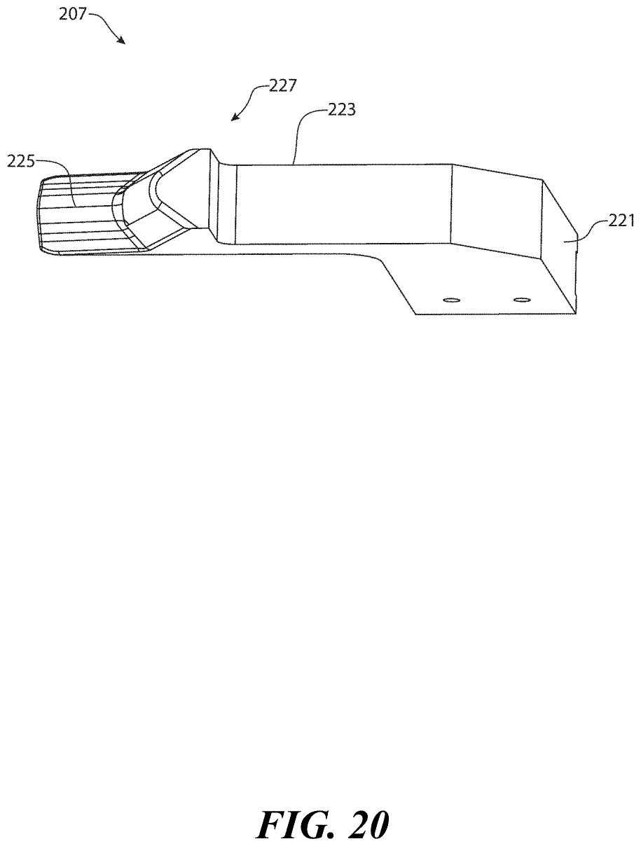

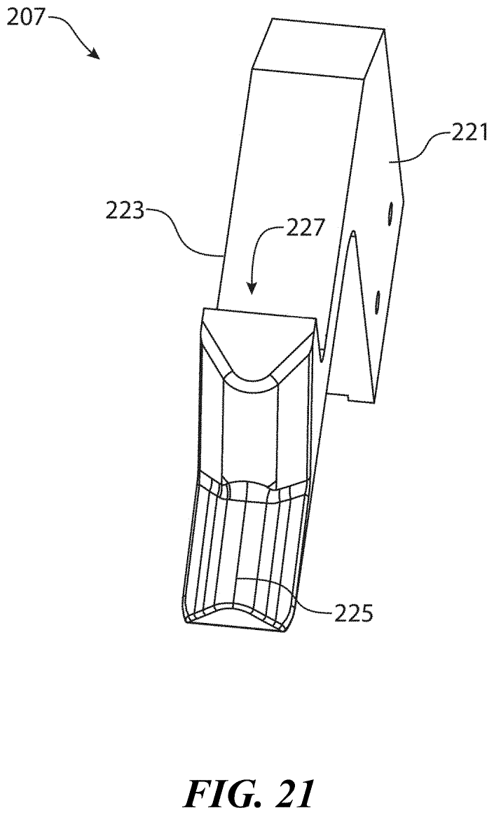

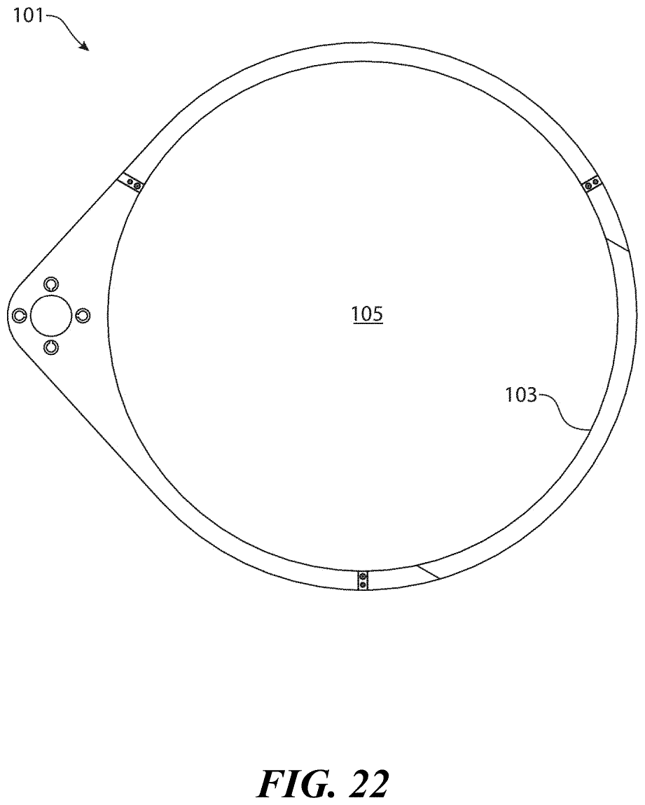

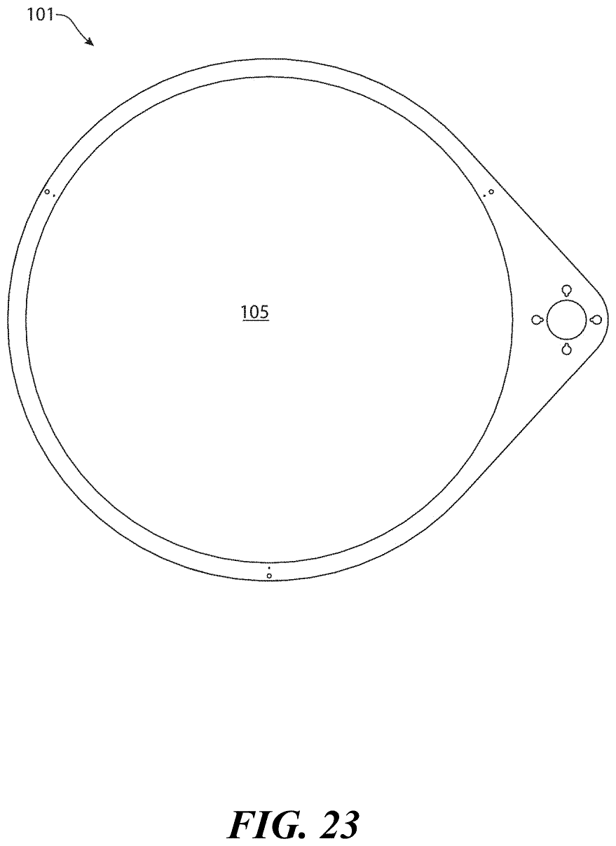

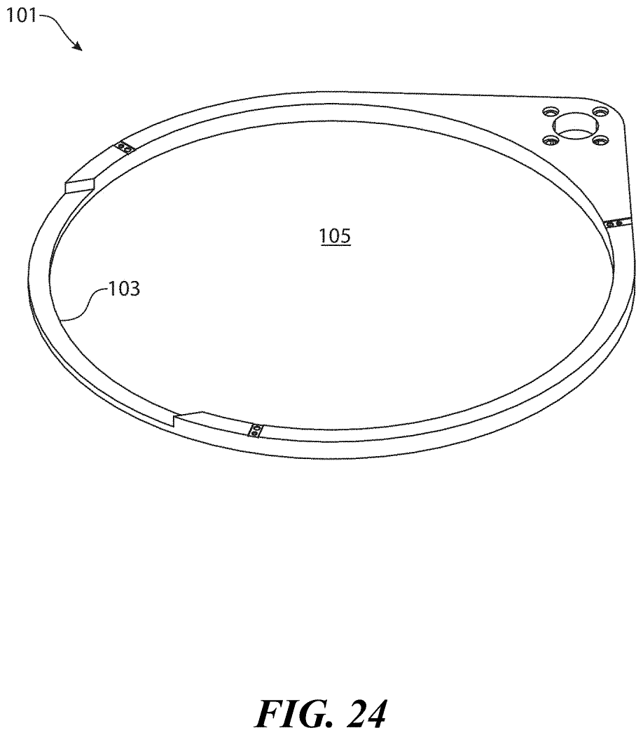

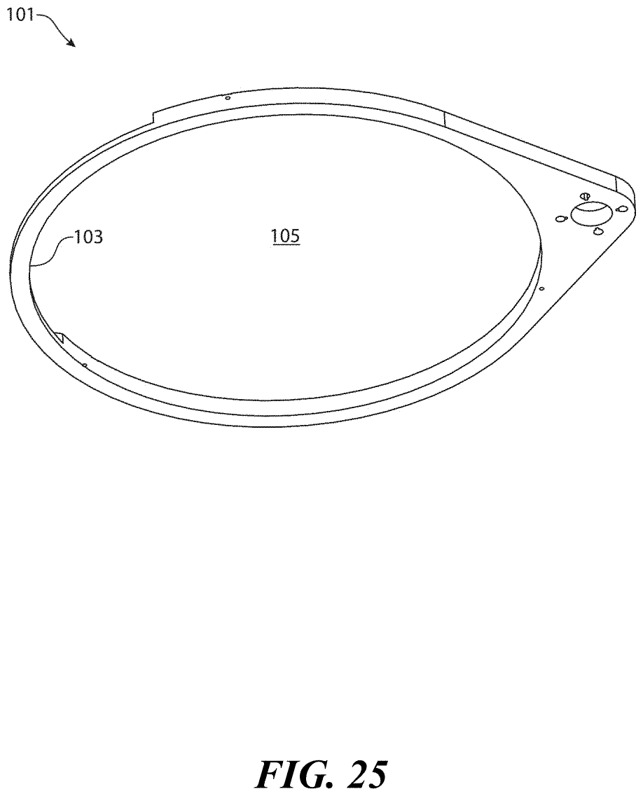

FIGS. 17-21 illustrate another embodiment of a wafer support structure 207 that may be substituted for the wafer support structure 107 of FIGS. 12-16 in some applications. As with the wafer support structure 107 of FIGS. 12-16, the wafer support structure 207 of FIGS. 17-21 includes a base 221 with a finger 223 protruding therefrom. Each finger 223 is equipped with a protrusion 225 thereon which supports a wafer. However, unlike the hemispherical protrusion in the wafer support structure 107 of FIGS. 12-16, in the wafer support structure 207 of FIGS. 17-21, this protrusion 225 takes the form of a ridge. Each finger 223 is further equipped with a stop 227 which is spaced apart from the protrusion 225. The stop 227 of the wafer support structure 207 has a (preferably non-planar) contact surface 231. In the particular embodiment depicted, this contact surface 231 is beveled or faceted, though in other embodiments in may be rounded.

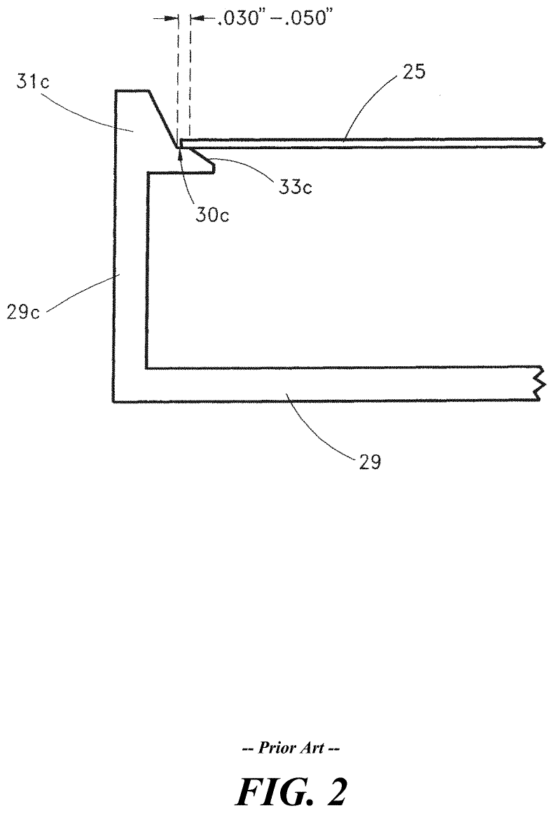

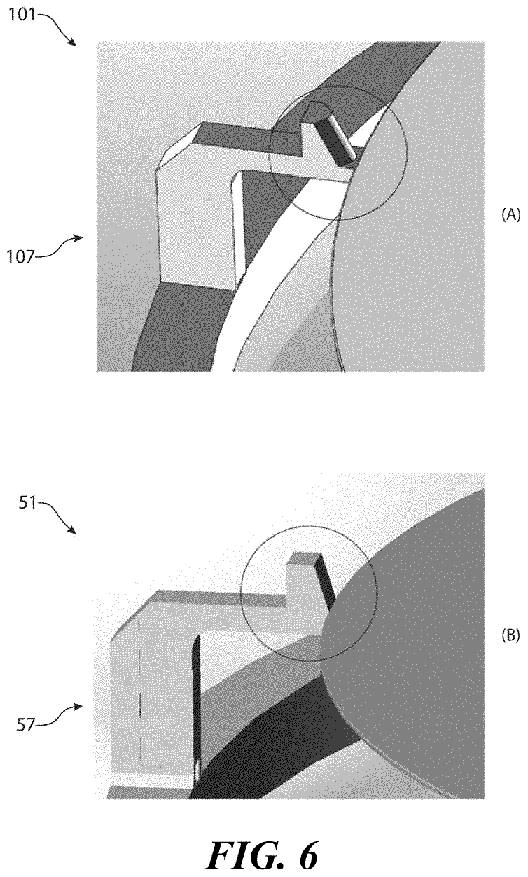

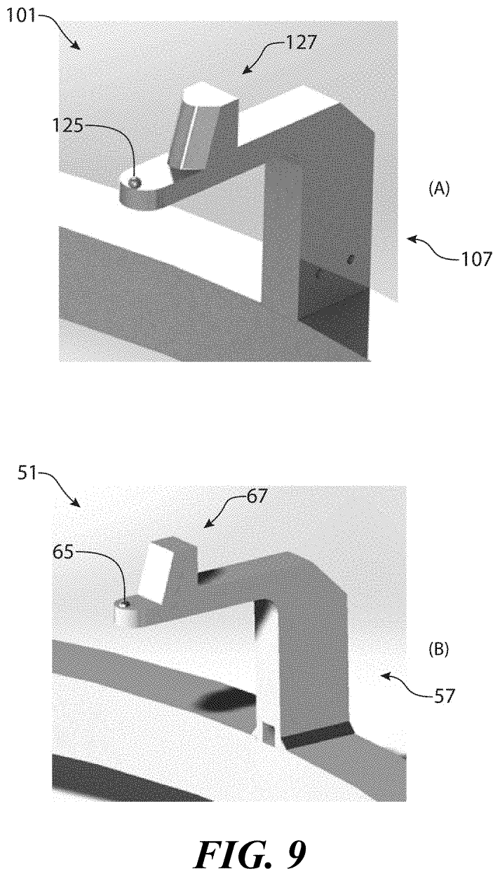

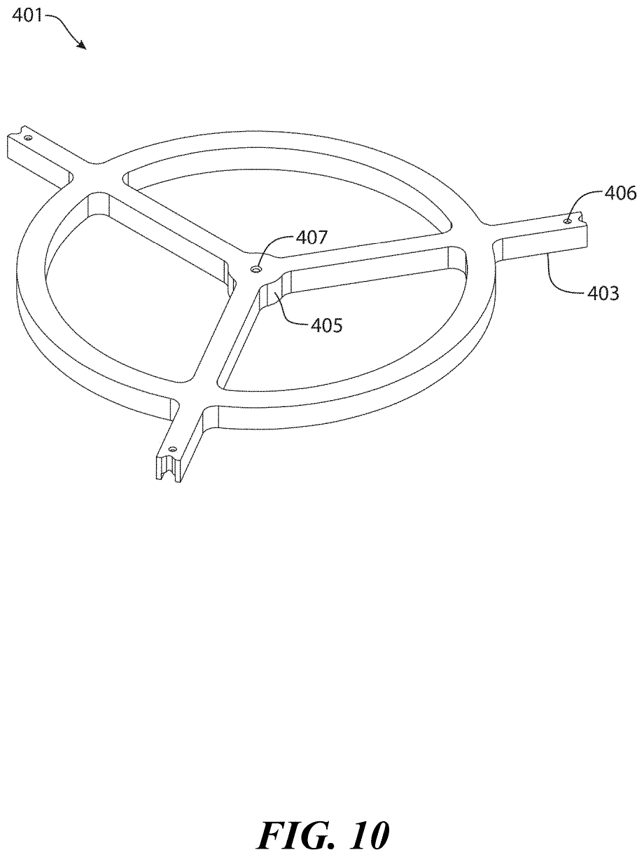

FIGS. 6 and 9 provide a comparison between the wafer support structures 107 of FIGS. 12-16 (see FIG. 6A and FIG. 9A) and a wafer support structure 57 of the prior art (see FIG. 9A and FIG. 9B). The wafer support structure 57 of FIG. 9B is similar to that depicted in FIG. 2, but is a slightly different version of it. As seen in FIG. 9, the spacing between the protrusion 125 and the contact surface 131 of the stop 127 (see FIG. 9A) in the lift hoop 101 of FIG. 4 is greater than the spacing between the protrusion 65 and the stop 67 in the prior art lift hoop 51. In the particular embodiment depicted, this difference is about 2.25 mm.

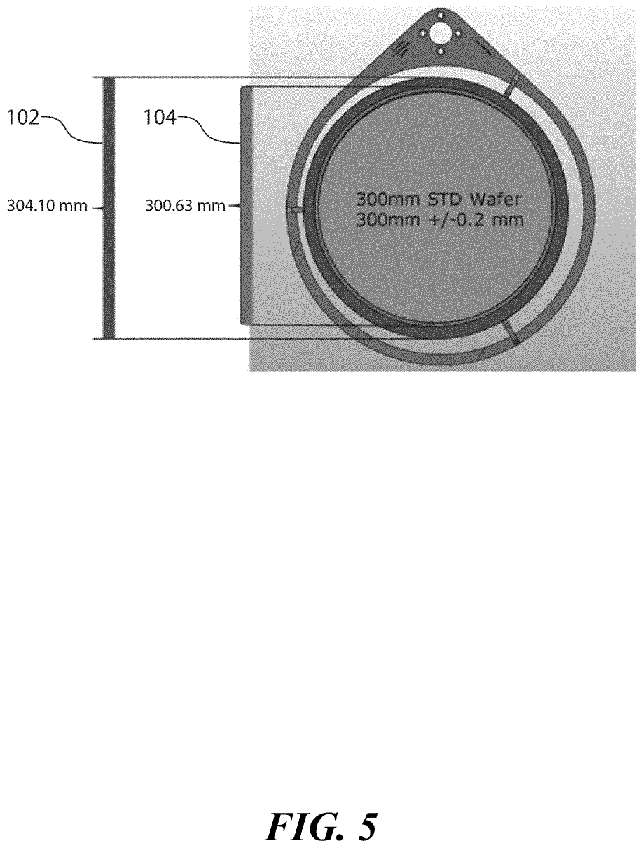

As seen in FIG. 5, this difference in spacing has a significant impact on the wafer capture area of the lift hoop. Thus, while the lift hoop 51 of FIG. 9B has a wafer capture area 104 with a diameter of about 300.63 (which is very close to the wafer diameter of 300 mm+/−0.2 mm), the lift hoop 101 of FIG. 9A has a wafer capture area 102 with a diameter of about 304.10 mm, and thus imparts more than 6 times as much radial play to the lift hoop. The increase in wafer capture area provided by the lift hoop 101 of FIG. 9A is found to provide significant reductions in contact between the stop 127 and the wafer, thus reducing particle generation while also allowing for smooth wafer hand-offs and care-free wafer handling.

Referring again to FIG. 9, while the stop 67 of the wafer support structure 57 of FIG. 9B has a planar contact surface 71, in contrast, the stop 127 of the wafer support structure 107 of FIG. 9A has a non-planar contact surface 131. This non-planar surface may be rounded, beveled or faceted, but preferably contains a point that forms the shortest distance between said stop and said protrusion. Without wishing to be bound by theory, the use of a non-planar surface is believed to reduce particle generation by providing a smaller area of contact in the event that the wafer comes into contact with the stop 127.

The non-planar contact surfaces 131 of the stop 127 and the surfaces of the protrusions 125 on the wafer support structure 107 of FIG. 9A are preferably smooth. Preferably, these surfaces have a surface roughness, as measured by ASME B46.1, within the range of about 20 Ra to about 40 Ra, more preferably within the range of about 25 Ra to about 35 Ra, and most preferably about 32 Ra. This is in contrast to the corresponding surfaces of the support structure 57 of FIG. 9B, which are significantly rougher. Without wishing to be bound by theory, this difference in surface roughness is believed to further minimize particle reduction in the devices and methodologies described herein.

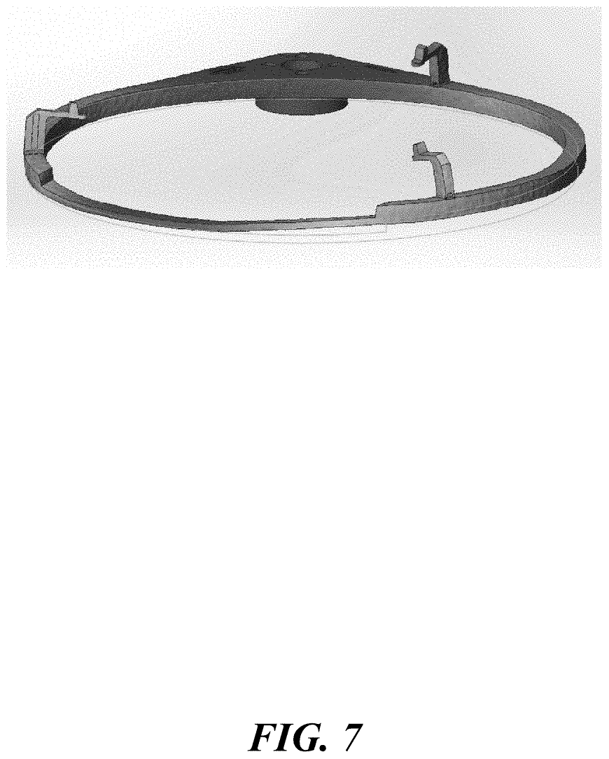

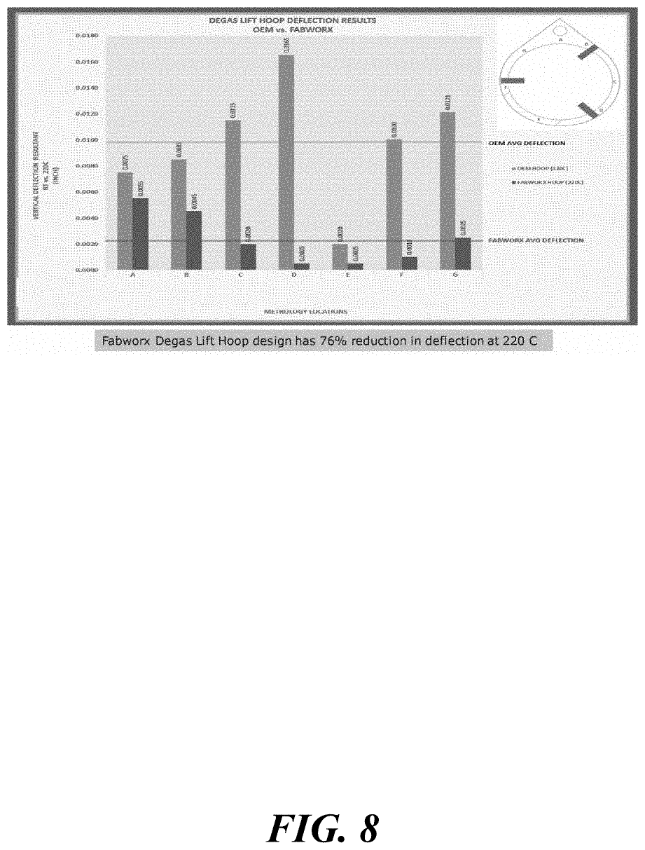

FIGS. 7-8 illustrate a further advantage of a preferred embodiment of a lift hoop of the type described herein, and a method for its manufacture. Lift hoops encounter significant heat gradients during their normal use, since they are designed for use in degassing chambers. However, it has been found that the effects of these heat gradients have not been properly accounted for in the manufacture of lift hoops. Consequently, as seen in FIG. 7, prior art lift hoops are frequently observed to undergo significant deformations across a thermal cycle (the original position of the lift hoop is indicated by dashed lines). This frequently results in a puckering of the lift hoop as seen in FIG. 7, a phenomenon known in the art as “potato chipping”. Such heat induced deformations may significantly reduce the wafer capture zone, may adversely affect the accuracy of wafer placement during wafer handling and hand-off operations, and may thus contribute to wafer contact and particle generation.

It has now been found that such heat induced deformations may be significantly reduced or eliminated by thermally annealing the lift hoop under pressure. This may be accomplished, for example, by placing the lift hoop (with the wafer support structures removed) between pneumatic clamps and then exposing the clamped lift hoop to one or more suitable thermal cycles. Such thermal cycles are preferably similar to or greater than those encountered by the lift hoop in a typical degassing process (for example, 200-450° C.). Notably, this process is facilitated by the ability to remove the wafer support structures. By contrast, in the OEM device, the wafer support structures are welded to the lift hoop. Hence, even if the OEM device were subjected to a thermal anneal, the presence of the permanently affixed wafer support structures would interfere with the process. Moreover, if the wafer support structures were welded on after the thermal anneal, some or all of the advantages of the thermal anneal could be lost due, for example, to recrystallization of the constituent metal alloys during the welding operation.

As seen in FIG. 8, this thermal anneal process is found to provide significant reductions in thermal deformation across the lift hoop. Thus, the graph depicted therein provides measures of thermal deflection for an OEM lift hoop and a lift hoop subject to the thermal anneal process described herein. As seen therein, significant improvements were observed at every point on the lift hoop, and an overall 76% reduction in thermally-induced deflection was observed.

Another issue encountered with prior art lift hoop devices relates to alignment. During use, an end effector is used to effect wafer hand-off within the degas chamber. In order to ensure proper wafer hand-off and uniform wafer processing, it is important for the end effector blade to position the wafer in the center of the degas chamber. This requires an alignment of the geometric centers of the wafer blade, the heater, and the lift hoop. At present, this is typically accomplished through the use of a pin to align the end effector blade with the heater. In particular, the pin extends through a first hole located in the geometric center of the end effector blade, and into a second hole located in the geometric center of the heater. However, alignment of the lift hoop with the end effector blade and the heater is left to the operator's eye, and hence does not lend itself to repeatability. The situation is compounded by the fact that the lift hoop is a complicated 3-dimensional device equipped with wafer support structures.

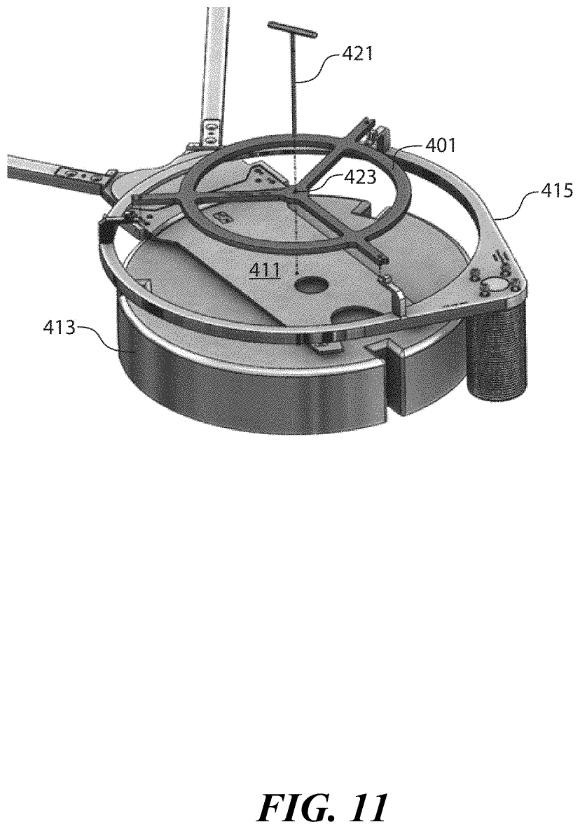

It has now been found that the foregoing issue may be overcome with the special fixture depicted in FIG. 11. As seen therein the fixture 401 includes a plurality of arms 403 which extend radially from a central portion 405. Each of the arms 403 has a terminal portion equipped with an aperture 406. The central portion 405 is equipped with a central aperture 407.

In use, when it is desired to align the end effector blade 411 with the degas chamber heater pedestal 413 and the lift hoop 415, the fixture 401 is placed on top of the lift hoop 415 such that the apertures on the arms 403 of the fixture 401 are aligned with the protrusions on the wafer support fixtures (see FIG. 9A). A pin 421 (of the type used in the OEM equipment to align the end effector blade 411 to the degas chamber heater pedestal 413) is then inserted through the central aperture 407, through an aperture 423 provided in the end effector blade 411, and into an aperture (not shown) which is provided in the degas chamber heater pedestal 413. The use of the fixture in this manner aligns the heater, end effector and lift hoop to each other simultaneously in a single operation.

The devices disclosed herein, and the components or portions thereof, may have certain ornamental, non-functional features which are amenable to design protection. One skilled in the art will appreciate that, although these devices are depicted in solid line drawings, various features in the drawings could be disclaimed (that is, could be rendered with dashed drawings in a design patent application) or claimed without departing from the scope of the present specification. Similarly, various combinations of such features could be claimed or disclaimed in a design patent application without departing from the scope of the present specification.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims. It will also be appreciated that the various features set forth in the claims may be presented in various combinations and sub-combinations in future claims without departing from the scope of the invention. In particular, the present disclosure expressly contemplates any such combination or sub-combination that is not known to the prior art, as if such combinations or sub-combinations were expressly written out.

1. A lift hoop, comprising:
a frame having a central opening;
a plurality of wafer support structures disposed on said frame, wherein each of said plurality of wafer support structures includes a base which is attached to said frame, and a finger which is attached to said base and which extends from said base in the direction of said central opening;
a protrusion disposed on said finger; and
a stop disposed upon said finger and spaced apart from said protrusion, said stop having a non-planar surface which faces the central opening and which contains a point that forms the shortest distance between said stop and said protrusion.

2. The lift hoop of claim 1, wherein said fingers extend over said central opening.

3. (canceled)

4. The lift hoop of claim 1, wherein the central opening has a circumference, and wherein the protrusion and stop are disposed within a right cylinder containing the circumference.

5. The lift hoop of claim 1, wherein each of said plurality of wafer support structures is removably attached to said frame.

6. The lift hoop of claim 1, wherein said hoop is equipped with a rim having a planar surface, and wherein said wherein each of said plurality of wafer support structures is removably attached to said planar surface.

7. The lift hoop of claim 1, wherein said stop is beveled.

8. The lift hoop of claim 1, wherein said non-planar surface of said stop is a faceted surface that includes a first facet which is disposed between second and third facets.

9. (canceled)

10. The lift hoop of claim 1, wherein said non-planar surface of said stop is rounded or semi-cylindrical.

11. (canceled)

12. The lift hoop of claim 1, wherein each of said fingers has a proximal end portion which is attached to said base and a distal end which is spaced apart from said proximal end portion, and wherein said protrusion is disposed on said distal end portion.

13. The lift hoop of claim 1, wherein said protrusion is a hemispherical protrusion.

14. The lift hoop of claim 1, wherein said stop has a faceted surface.

15. In combination with the lift hoop of claim 1, a semiconductor processing chamber which is equipped with a heating element and a pedestal, wherein said lift hoop is releasably attached to said heating element.

16. (canceled)

17. The lift hoop of claim 1, wherein said finger is mounted on said base with threaded fasteners.

18-20. (canceled)

21. The lift hoop of claim 1, in combination with a semiconductor wafer, wherein said lift hoop provides a wafer capture area having a diameter that exceeds the diameter of the wafer by at least 1 mm.

22-23. (canceled)

24. A method for making a lift hoop, comprising:
providing a frame having a central opening therein;
thermally annealing the frame while applying pressure to the frame; and
releasably attaching a plurality of wafer support structures to said frame, wherein each of said plurality of wafer support structures includes (a) a base which is removably attached to said frame, (b) a finger which is attached to said base and which extends from said base in the direction of said central opening, (c) a protrusion disposed on said finger, and (d) a stop disposed upon said finger and spaced apart from said protrusion.

25. The method of claim 24, wherein the lift hoop is used in a degassing process, and wherein thermally annealing the frame includes subjecting the frame to a thermal cycle that includes the thermal cycle used in the degassing process.

26. The method of claim 24, wherein thermally annealing the frame while applying pressure to the frame includes subjecting the frame to a thermal cycle while applying pressure to the frame with a set of clamps.

27. The method of claim 24, wherein said stop has a non-planar surface which faces said central opening and which contains a point that forms the shortest distance between said stop and said protrusion.

28. A method for aligning an end effector blade with a degas chamber, comprising:
providing an end effector blade with a keying aperture disposed therein;
providing a degas chamber having a lift hoop and heater pedestal, wherein said heater pedestal has a flattened surface with a centrally located aperture therein, and wherein said lift hoop includes a frame with a central opening therein, and a plurality of wafer support structures disposed on said frame, wherein each of said plurality of wafer support structures includes a base which is attached to said frame, and a finger which is attached to said base and which extends from said base in the direction of said central opening, and wherein each of said plurality of wafer support structures further includes a protrusion disposed on said finger;
providing a fixture having a central hub with a plurality of arms extending therefrom, wherein said hub has a central aperture therein, and wherein each of said plurality of arms has a peripheral aperture in a terminal portion thereof;
placing said fixture on said lift hoop such that each of said peripheral apertures engages a protrusion of one of said fingers, and such that the central aperture in said fixture is coaxially aligned with the centrally located aperture in said heater pedestal; and
manipulating the position of the end effector until a pin inserted through the central aperture in said hub passes through the keying aperture in said end effector blade and into the centrally located aperture in said heater pedestal.

29. The method of claim 28, wherein said flattened surface of said heater pedestal has a geometric center, and wherein said centrally located aperture is disposed at the geometric center of said flattened surface.
